(19) United States
(12) Patent Application Publication
(10) Pub. No.: US 2026/0129803 A1
(43) Pub. Date: May 7, 2026

(54) LIQUID-COOLING HEAT-DISSIPATION PLATE HAVING SPARSELY ARRANGED PIN-FINS AND DENSELY ARRANGED PIN-FINS

(71) Applicant: AMULAIRE THERMAL TECHNOLOGY, INC., New Taipei City (TW)

(72) Inventors: YI-HSIN HUANG, New Taipei City (TW); KUO-WEI LEE, New Taipei City (TW); TZE-YANG YEH, New Taipei City (TW); CHIEN-CHENG WU, New Taipei City (TW); CHUN-LUNG WU, New Taipei City (TW); CHING-MING YANG, New Taipei City (TW); MING-HSUAN CHANG, Taoyuan City (TW)

(21) Appl. No.: 18/939,705

(22) Filed: Nov. 7, 2024

(51) Int. Cl. H05K 7/20

(52) U.S. Cl. CPC H05K 7/20409

(57) ABSTRACT

A liquid-cooling heat dissipating plate with sparsely arranged pin-fins and densely arranged pin-fins includes a heat dissipating plate body and a plurality of pin-fins. The heat dissipating plate body has a first heat dissipating face and a second heat dissipating face being opposite to each other. The first heat dissipating face is for contacting a plurality of chips, and an angle between a chip arrangement direction and a cooling liquid flowing direction is between 65° to 115°. The second heat dissipating face is for contacting the cooling liquid, with the plurality of pin-fins being formed thereon. A plurality of sparse regions with lower fin density and a plurality of dense regions with higher fin density are configured on the heat dissipating plate body, such that a flow speed of the cooling liquid along the cooling liquid flowing direction increases when the cooling liquid flows through each sparse region.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a liquid-cooling heat dissipation plate, and more particularly to a liquid-cooling heat dissipation plate with sparsely arranged pin-fins and densely arranged pin-fins.

### BACKGROUND OF THE DISCLOSURE

Heat sinks are quite common in the applications of various products. Generally, advanced products usually adopt water/liquid-cooling heat sinks, which have the advantages of being more silent and providing stable cooling compared to wind-cooling heat sinks. However, for a plurality of chips of the power modules used in electric vehicles, which are running at increasingly faster speeds, the liquid-cooling heat sinks are no longer able to satisfy the needs for heat dissipation of these chips. Therefore, how to conduct heat dissipation more efficiently through liquid-cooling technology has long been an issue to be addressed in the relevant industry.

### SUMMARY OF THE DISCLOSURE

In response to the above-referenced technical inadequacy the present disclosure provides a liquid-cooling heat dissipation plate with sparsely arranged pin-fins and densely arranged pin-fins.

In order to solve the above-mentioned problems, one of the technical aspects adopted by the present disclosure is to provide a liquid-cooling heat dissipating plate with sparsely arranged pin-fins and densely arranged pin-fins for being arranged in a closed liquid-cooling heat sink, including: a heat dissipating plate body with a first heat dissipating surface for contacting a plurality of chips and a second heat dissipating face for contacting a cooling liquid, the first heat dissipating surface and the second heat dissipating surface being opposite to each other, and a plurality of pin-fins formed on the second heat dissipating face of the heat dissipating plate body, in which an angle between a chip arrangement direction and a cooling liquid flowing direction is between 65° to 115°, and the plurality of pin-fins are divided into a plurality of sparse regions with lower fin density and a plurality of dense regions with higher fin density on the heat dissipating plate body along a degree of 65° to 115° of the cooling liquid flowing direction, such that a flow speed of the cooling liquid along the cooling liquid flowing direction increases when the cooling liquid flows through each of the sparse regions.

In one of the possible or preferred embodiments, a fin total surface area per unit area of the sparse region is 0% to 20% of a fin total surface area per unit area of the dense region.

In one of the possible or preferred embodiments, the distance between each of the pin-fins is between 0.5 to 1.5 mm.

In one of the possible or preferred embodiments, a maximum projection width of the sparse region is 20% to 100% of a projection width of the chip.

In one of the possible or preferred embodiments, the pin-fins are formed by metal injection molding or forging, and a draft angle of the pin-fins is between 0° to 5°.

In one of the possible or preferred embodiments, the plurality of sparse regions and the plurality of dense regions are distributed at an upstream side and/or a downstream side of the plurality of chips along the cooling liquid flowing direction.

In one of the possible or preferred embodiments, the plurality of chips are defined as a chip cluster by three or more than three chips arranged along the chip arrangement direction, and the upstream side and the downstream side of a central chip of the chip cluster are configured to have the sparse regions arranged thereon.

In one of the possible or preferred embodiments, when the number of the chips of the chip cluster is odd, the central chip of the chip cluster is one of the plurality of chips disposed at a center of the chip cluster, and when the number of the chips of the chip cluster is even, the central chip of the chip cluster is two of the plurality of chips disposed at a center of the chip cluster.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a first embodiment of the present disclosure;

FIG. 2 is a schematic cross-sectional view of FIG. 1 along line II-II;

FIG. 3 is a schematic view of a fin density per unit area of a sparse region of the present disclosure;

FIG. 4 is a schematic view of a fin density per unit area of a dense region of the present disclosure;

FIG. 5 is a schematic side view of a pin-fin of the present disclosure; and

FIG. 6 is a schematic top view of a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

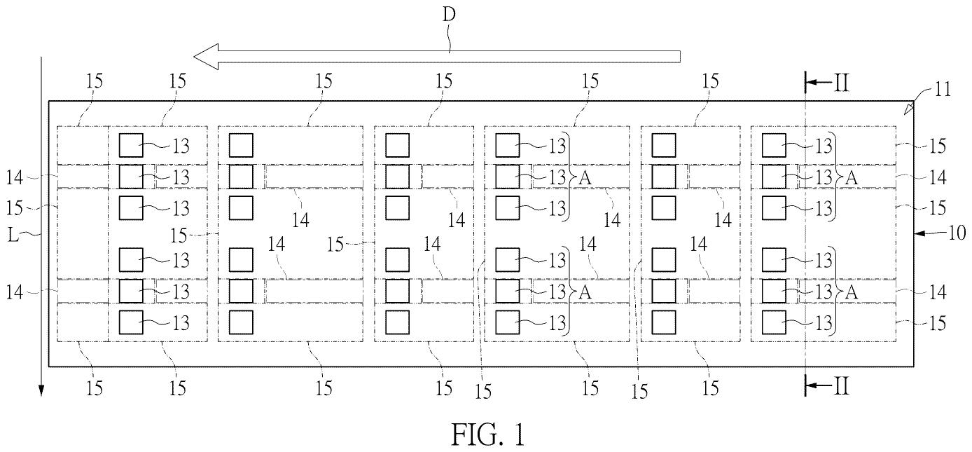

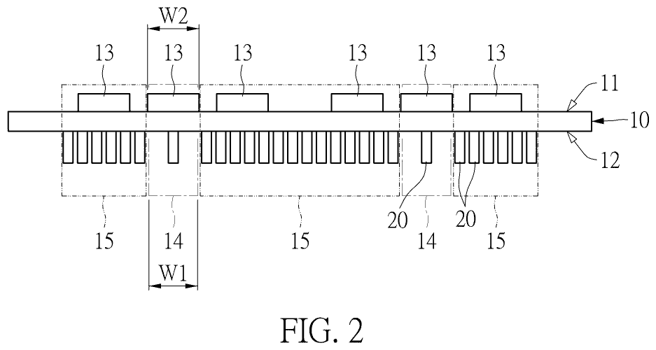

Referring to FIG. 1 to FIG. 5, a first embodiment of the present disclosure provides a liquid-cooling heat dissipation plate with sparsely arranged pin-fins and densely arranged pin-fins for being arranged in a closed liquid-cooling heat sink, and the configuration of the closed liquid-cooling heat sink is not limited. As shown in FIGS. 1 and 2, the liquid-cooling heat dissipation plate with sparsely arranged pin-fins and densely arranged pin-fins provided by the present disclosure essentially includes a heat dissipating plate body 10 and a plurality of pin-fins 20.

In the present embodiment, the heat dissipating plate body 10 may be made of highly thermo-conductive materials, such as copper, copper alloy, aluminum, and aluminum alloy. Moreover, the heat dissipating plate body 10 has a first heat dissipating face 11 and a second heat dissipating face 12 that are opposite to each other.

Furthermore, the first heat dissipating face 11 in the present embodiment is for contacting a plurality of chips 13, which may be direct contact or the contact through an intermediate component, and an angle between the chip arrangement direction L and the cooling liquid flowing direction D is between 65° to 115°. The second heat dissipating face 12 in the present embodiment is for contacting the cooling liquid (such as water or ethylene glycol).

In the present embodiment, the plurality of pin-fins 20 may be formed on the second heat dissipating face 12 of the heat dissipating plate body 10. Furthermore, the plurality of pin-fins 20 and the heat dissipating plate body may be integrally formed, so as to have material continuity. In addition, the heat dissipating plate body 10 may be formed by forging.

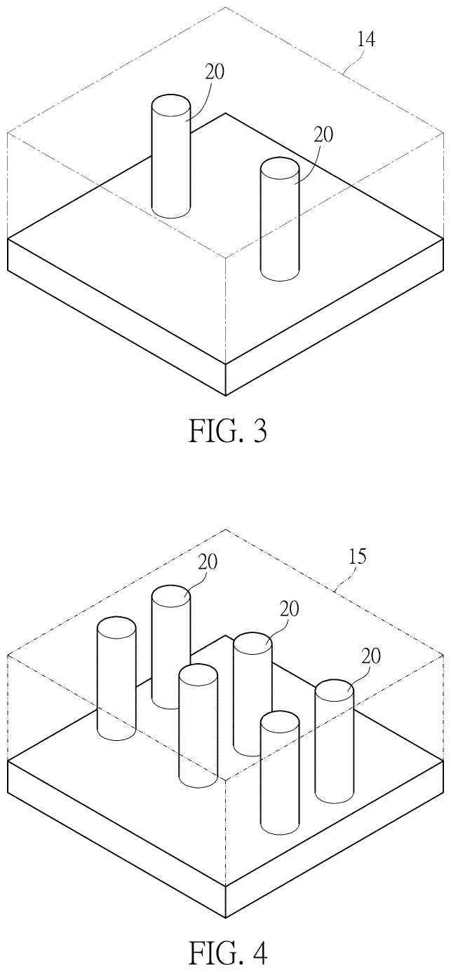

In the present embodiment, the plurality of pin-fins 20 are divided into a plurality of sparse regions 14 with lower fin density and a plurality of dense regions 15 with higher fin density on the heat dissipating plate body 10, i.e., the fin density per unit area of the sparse region 14 is lower (as shown in FIG. 3), and the fin density per unit area of the dense region 15 is higher (as shown in FIG. 4). Furthermore, as shown in FIGS. 1 and 2, the plurality of pin-fins 20 of the present embodiment are divided into a plurality of sparse regions 14 and a plurality of dense regions 15, which may be arranged alternately, on the heat dissipating plate body 10 along 65° to 115° from the cooling liquid flowing direction D, such that the flowing speed of the cooling liquid along the cooling liquid flowing direction D increases when the cooling liquid flows through each of the sparse regions 14, so as to quickly remove the high heat, dissipate the overall heat, and make the temperature thereof uniform.

In order to increase the flow speed of the cooling liquid along the cooling liquid flowing direction D when the cooling liquid flows through each of the sparse regions 14, the fin total surface area per unit area of the sparse region 14 is 0% to 20% of the fin total surface area per unit area of the dense region 15. Also, the distance between each of the pin-fins 20 is between 0.5 to 1.5 mm. In addition, the maximum projection width W1 of the sparse region 14 can be 20% to 100% of the projection width W2 of the chip 13. In other words, the maximum projection width W1 of the sparse region 14 can only be less or equal to the projection width W2 of the chip 13, and cannot be greater than the projection width W2 of the chip 13.

Moreover, the plurality of sparse regions 14 and the plurality of dense regions 15 are distributed at the upstream side and/or the downstream side of these chips 13 along the cooling liquid flowing direction D. Also, the chips 13 are defined as a chip cluster A by three or more than three chips 13 arranged along a chip arrangement direction L, and the central chip of the chip cluster A will be hotter because of being affected by the heat of the chips at the both sides thereof. Therefore, the upstream side and the downstream side of the central chip are configured to have the sparse regions 14 arranged thereon to allow high heat to be rapidly removed by the cooling liquid.

In the present embodiment, the chips 13 are defined as the chip cluster A by three of the chips 13 arranged along the chip arrangement direction L. That is, when the number of the chips of the chip cluster is odd, the central chip of the chip cluster A refers to one of the chips 13 disposed at the center of the chip cluster A.

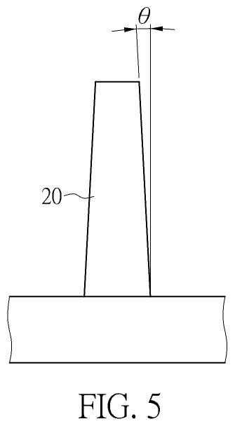

In the present embodiment, the pin-fins 20 may be formed by metal injection molding (MIM), and may be formed by forging, and the draft angle θ of the pin-fins 20 (as shown in FIG. 5) is between 0° to 5°.

### Second Embodiment

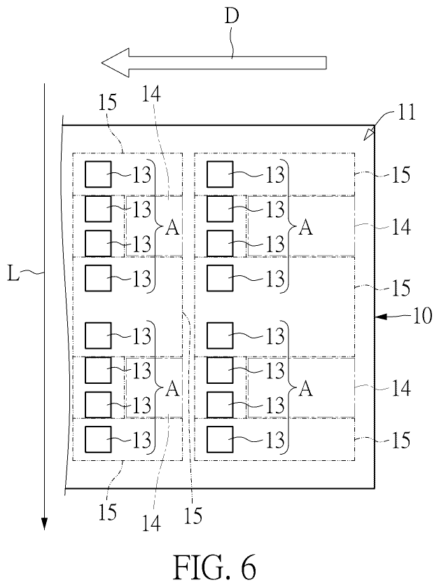

Referring to FIG. 6, a second embodiment of the present disclosure that is similar to the first embodiment is illustrated, with the main differences therebetween being described below.

In the present embodiment, the chips 13 are defined as a chip cluster A by four chips 13 arranged along the chip arrangement direction L. That is, when the number of the chips of the chip cluster A is even, the central chip of the chip cluster A refers to two of the chips 13 that are the nearest to the center of the chip cluster A, and the two chips 13 at the center of the chip cluster A will be hotter because of being affected by the heat of the chips at the both sides thereof. Therefore, the upstream side and the downstream side of the two central chips are configured to have the sparse regions 14 arranged thereon to allow high heat to be rapidly removed by the cooling liquid.

In summary, the liquid-cooling heat dissipation plate with sparsely and densely arranged pin-fins for being disposed in the closed liquid-cooling heat sink provided by the present disclosure includes a heat dissipating plate body and a plurality of pin-fins. The heat dissipating plate body has a first heat dissipating face and a second heat dissipating face that are opposite to each other. The first heat dissipating plate is for forming contact with a plurality of chips, and the angle between the chip arrangement direction and the cooling liquid flowing direction is between 65° to 115°. The second heat dissipating face is used for contacting the cooling liquid. The plurality of pin-fins are formed on the second heat dissipating face of the heat dissipating plate body, and the plurality of pin-fins are divided into a plurality of sparse regions with lower fin density and a plurality of dense regions with higher fin density on the heat dissipating plate body along 65° to 115° from the cooling liquid flowing direction, such that the flowing speed of the cooling liquid along the cooling liquid flowing direction increases when the cooling liquid flows through each of the sparse regions, so as to rapidly remove the high heat, dissipate the overall heat, and make the temperature of the heat dissipation plate uniform.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A liquid-cooling heat dissipating plate having sparsely arranged pin-fins and densely arranged pin-fins for being arranged in a closed liquid-cooling sink, comprising:
a heat dissipating plate body having a first heat dissipating surface for contacting a plurality of chips and a second heat dissipating surface for contacting a cooling liquid, wherein the first heat dissipating surface and the second heat dissipating surface are opposite to each other; and a plurality of pin-fins formed on the second heat dissipating face of the heat dissipating plate body;
wherein an angle between a chip arrangement direction and a cooling liquid flowing direction is between 65° to 115°, and the plurality of pin-fins are divided into a plurality of sparse regions with lower fin density and a plurality of dense regions with higher fin density on the heat dissipating plate body along a degree of 65° to 115° of the cooling liquid flowing direction, which increases a flow speed of the cooling liquid along the cooling liquid flowing direction when the cooling liquid flows through each of the sparse regions.

2. The liquid-cooling heat dissipating plate according to claim 1, wherein a fin total surface area per unit area of the sparse region is 0% to 20% of a fin total surface area per unit area of the dense region.

3. The liquid-cooling heat dissipating plate according to claim 1, wherein a distance between each of the plurality of pin-fins is between 0.5 to 1.5 mm.

4. The liquid-cooling heat dissipating plate according to claim 1, wherein a maximum projection width of the sparse region is 20% to 100% of a projection width of the chip.

5. The liquid-cooling heat dissipating plate according to claim 1, wherein the pin-fins are formed by metal injection molding or forging, and a draft angle of the pin-fins is between 0° to 5°.

6. The liquid-cooling heat dissipating plate according to claim 1, wherein the plurality of sparse regions and the plurality of dense regions are distributed at an upstream side and/or downstream side of the plurality of chips along the cooling liquid flowing direction.

7. The liquid-cooling heat dissipating plate according to claim 1, wherein the plurality of chips are defined as a chip cluster by three or more than three chips arranged along the chip arrangement direction, and the upstream side and the downstream side of a central chip of the chip cluster are configured to have the sparse regions arranged thereon.

8. The liquid-cooling heat dissipating plate according to claim 7, wherein, when the number of the chips of the chip cluster is odd, the central chip of the chip cluster is one of the plurality of chips disposed at a center of the chip cluster, and when the number of the chips of the chip cluster is even, the central chip of the chip cluster is two of the plurality of chips disposed at a center of the chip cluster.
